(19) United States
(12) Patent Application Publication
(10) Pub. No.: US 2003/0095439 A1
(43) Pub. Date: May 22, 2003

(54) Method and system for minimizing bit stress in a non-volatile memory during erase operations

(75) Inventors: Kemal T. San, Plano, TX (US); Stephen K. Heinrich-Barna, Murphy, TX (US); Robert L. Pitts, Dallas, TX (US); Atif Hussain, Dallas, TX (US)

Correspondence Address: TEXAS INSTRUMENTS INCORPORATED, P O BOX 655474, M/S 3999, DALLAS, TX, 75265

(73) Assignee: Texas Instruments Incorporated

(21) Appl. No.: 09/990,565

(22) Filed: Nov. 20, 2001

(51) Int. Cl. G11C 11/34

(52) U.S. Cl. 365/185.22

(57) ABSTRACT

A method and system for minimizing bit stress in a non-volatile memory during an erase operation are disclosed, which can increase the absolute value of the gate voltage of a memory cell incrementally with each subsequent high voltage erase pulse during the erase operation, instead of ramping up the absolute value of the gate voltage completely during each pulse. Also, each high voltage pulse can be conditioned so that its leading edge does not transition too quickly. Furthermore, a state machine for a flash memory device is disclosed, which can perform, among other things, the erase functions and/or algorithms used for the flash memory.

### TECHNICAL FIELD OF THE INVENTION

The present invention relates in general to non-volatile memory devices and, in particular, to a method and system for minimizing bit stress in a non-volatile memory device, such as a flash memory, during an erase operation.

### BACKGROUND OF THE INVENTION

Non-volatile memory is used to store data in a device where the data has to be maintained even when the device is not connected to a power supply. For example, non-volatile memory is used in personal computers to store instructions for completing basic tasks, such as interfacing with a keyboard or accessing a disk drive. A common type of non-volatile memory is flash EEPROM memory. Unlike many other types of non-volatile memory devices, data in flash EEPROM memory devices can be erased and rewritten.

In order to erase bits in a stacked gate flash EEPROM memory device, for example, high voltage pulses are applied across either the gate-to-source or gate-to-bulk nodes of a flash bit cell in a source-erase or channel-erase memory array, respectively. Typically, several such high voltage erase pulses are required. Also, a measurement has to be made during the interval between each pulse in order to determine if the bit has been erased, because each pulse moves the bit's threshold a slight amount (delta) away from it's previous value. However, by moving the bit thresholds, these high voltage pulses have an impact on and stress the bit(s) being erased.

Previous attempts to solve this bit stress problem demonstrated that by slowly increasing the absolute value of the gate voltage during an erase cycle, the stress on the bits could be minimized. Certain attempts to minimize bit stress in prior EEPROM memories used pulse-shaping techniques to ramp the absolute voltage of the gate voltage from a low value to a significantly higher value. This solution resulted in some lessening of bit stress to a small extent. However, the absolute value of the gate voltage is ramped up completely during each erase pulse, which still stresses the bits to a significant extent.

### SUMMARY OF THE INVENTION

Accordingly, a need has arisen for an improved method and system for minimizing bit stress in a non-volatile memory during an erase operation. As such, the present invention provides a method and system for minimizing bit stress in a non-volatile memory, which addresses the shortcomings of prior methods and systems.

According to one embodiment of the present invention, a method and system are provided for increasing the absolute value of the gate voltage of a flash memory cell incrementally with each subsequent high voltage pulse during an erase operation, instead of ramping up the gate voltage completely during each pulse. Also, in accordance with the present invention, each high voltage pulse can be suitably conditioned so that the leading edge of the pulse does not transition too quickly.

According to a second embodiment of the present invention, a state machine for a flash memory device is provided, which can perform, among other things, erase functions and/or algorithms used for the flash memory.

An important technical advantage of the present invention is that at the time when the silicon for a non-volatile memory array, such as for example, a flash EEPROM memory array, is being characterized, optimum starting voltage(s), ending voltage(s), and incremental voltage(s) for an erase operation can be determined and programmed for implementation with that non-volatile memory.

Another important technical advantage of the present invention is that a method and system are provided that can optimize design flexibility for minimizing bit stress in non-volatile memory devices during erase operations.

Still another important technical advantage of the present invention is that a method and system are provided that can minimize bit stress during erase operations in non-volatile memory devices, to a significantly greater extent than prior methods or systems.

Other technical advantages of the present invention will be readily apparent to one skilled in the art from the following figures, description and claims.

### BRIEF DESCRIPTION OF THE DRAWINGS

For a more complete understanding of the present invention and its advantages, reference is now made to the following descriptions, taken in conjunction with the accompanying drawings, in which:

FIG. 1 is a block diagram showing a flash memory module, which can be used to implement one embodiment of the present invention;

FIG. 2 is a state diagram showing an example of components and command and status signal flows for a flash state machine, in accordance with one embodiment of the present invention; and

FIG. 3 is a flow diagram showing a method that can be implemented, for example, by an execution unit of a flash state machine to perform an erase operation and minimize bit stress, in accordance with one embodiment of the present invention.

### DETAILED DESCRIPTION OF THE INVENTION

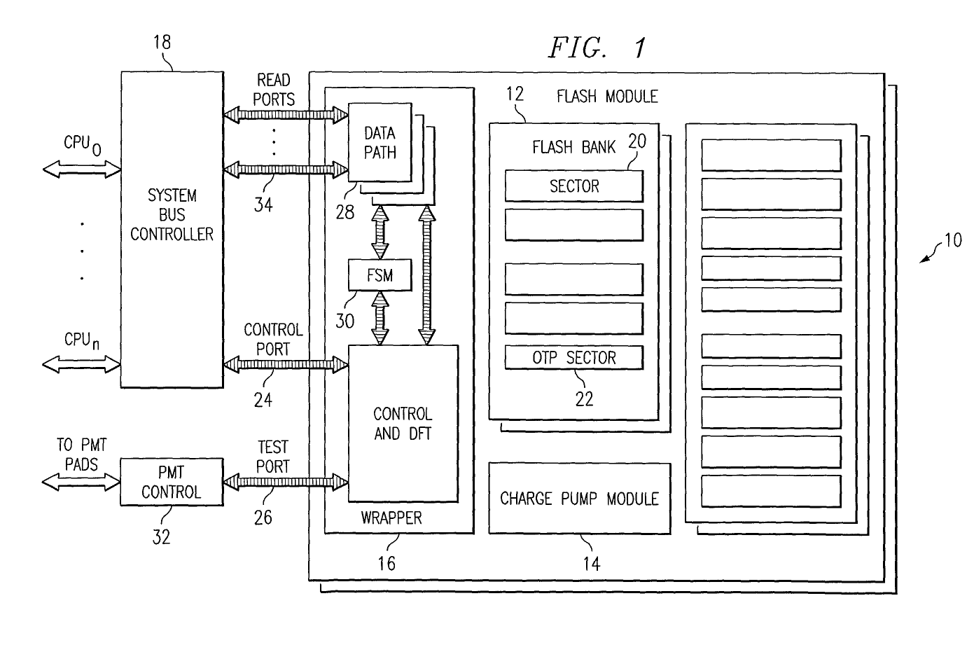

The preferred embodiment of the present invention and its advantages are best understood by referring to FIGS. 1-3 of the drawings, like numerals being used for like and corresponding parts of the various drawings.

FIG. 1 is a block diagram showing a flash memory module 10, which can be used to implement one embodiment of the present invention. For this illustrative example, flash memory module 10 can form part of a non-volatile, electrically erasable and programmable memory that is divided into sectors. Each memory sector can be erased independently of the other sectors. All memory bits in a sector can be erased simultaneously. Preferably, but not by way of limitation, each flash memory bit can be a stacked gate transistor, which can be erased using, for example, a Fowler-Nordheim tunneling approach. The flash memory implementation shown in FIG. 1 can enable multiple banks of flash memory to be accessed simultaneously by a host system.

More specifically, flash memory module 10 can include one or more flash banks 12. A flash bank 12 can be a group of flash memory sectors that share input/output buffers, data paths, sense amplifiers, and control logic. Flash banks 12 can support sector sizes from 64 Kb to 1 Mb of memory. Each flash bank 12 can include up to 16 Mb of memory for program and/or data storage, and a data path module 28 having a width of 16, 32, or 64 bits. For this example, a sector (e.g., also can be referred to as a segment or block) is a contiguous region of flash memory that can be erased simultaneously. Flash memory module 10 can also include a charge pump unit 14 (e.g., voltage generators and associated control) and a wrapper unit 16 (e.g., interface circuitry between a host system, the flash banks 12 and charge pump unit 14). Each flash bank 12 can include up to 32 sectors, and an optional One Time Programmable (OTP) sector 22 (non-erasable memory typically for customer use).

A flash wrapper unit 16 can include a read port 34 for each flash bank 12, a bi-directional control port 24, and a test port 26 (to support external testing). Preferably, each read port 34 has a bus width that is the same as that of the associated flash bank 12. The control port 24 can enable a user to configure and monitor the status of flash memory module 10, provide commands to the flash state machine 30, and read OTP sector 22. As such, control port 24 can provide a command and status interface between a host and the flash memory module 10. This port allows the host to read from and write to registers within the flash memory module 10. Also, commands to perform program, erase, and validation operations can be presented to flash memory module 10 via control port 24. The data path modules 28 can administer all handshaking functions in a read mode of operation.

Flash memory module 10 can function in a normal operating mode and one or more test modes. In a normal operating mode, mode flash program and erase commands are supplied to state machines (e.g., 30), which can automatically generate all voltages and clocks used to complete the desired operations. Preferably, if a flash bank 12 is not being programmed, erased, or validated, it is then (by default) available for a read operation, and requires no support from a state machine. A system bus controller 18 and PMT control 32 can perform the system and test input/output control operations, respectively.

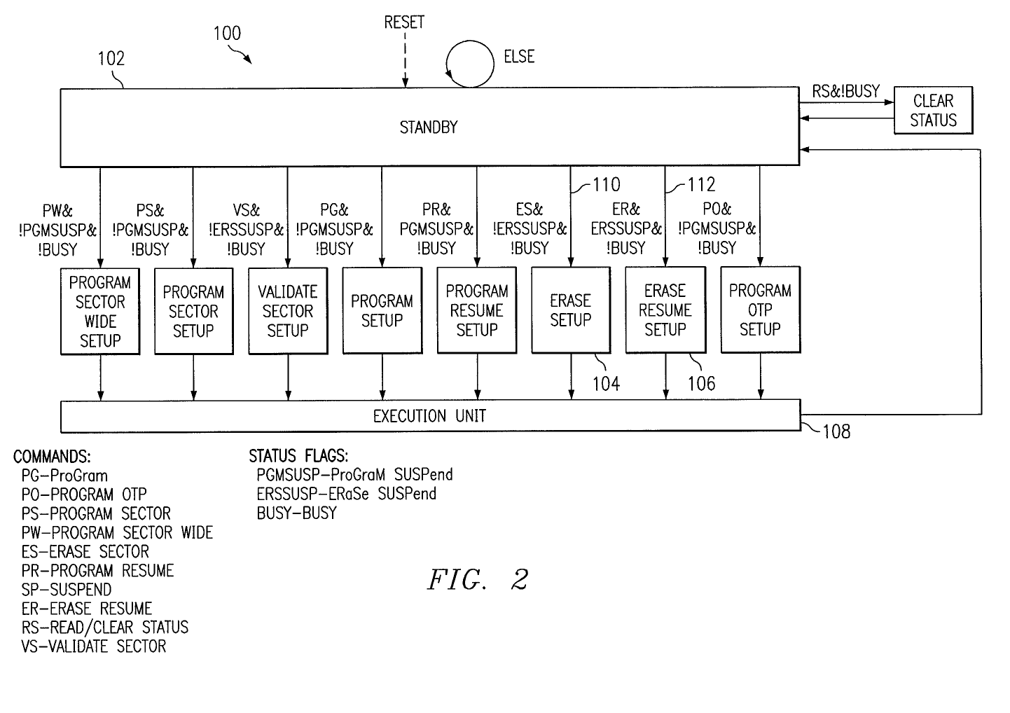

FIG. 2 is a state diagram 100 showing an example of command and status signal flows for a flash state machine (e.g., flash state machine 30 in FIG. 1), in accordance with one embodiment of the present invention. For one example embodiment, an 18F05 Flash Module developed by Texas Instruments Inc. includes an F05 Flash State Machine, which can be used to implement flash state machine 30. As such, flash state machine 30 can combine the command and write state machines for the flash memory module 10. Although a number of different states (e.g., program, erase, validate) are shown in FIG. 2, the erase states are of primary interest with respect to implementation of the present invention. For example, in order for flash state machine 30 to change from a standby mode 102 of operation to an erase setup mode 104, the command signal “Erase Sector” and the status flags “Not Erase Suspend” and “Not Busy” can be supplied from flash memory module 10 to flash state machine 30. In response, flash state machine 30 can prompt execution unit 108 to initiate an erase operation. If an erase operation is suspended for any suitable reason, the command signal “Erase Resume” and the status flags “Erase Suspend” and “Not Busy” can be supplied from flash memory module 10 to flash state machine 30, in order for flash state machine 30 to change from standby mode 102 to an erase resume setup mode 106. In response, flash state machine 30 can prompt execution unit 108 to resume an erase operation that has been suspended.

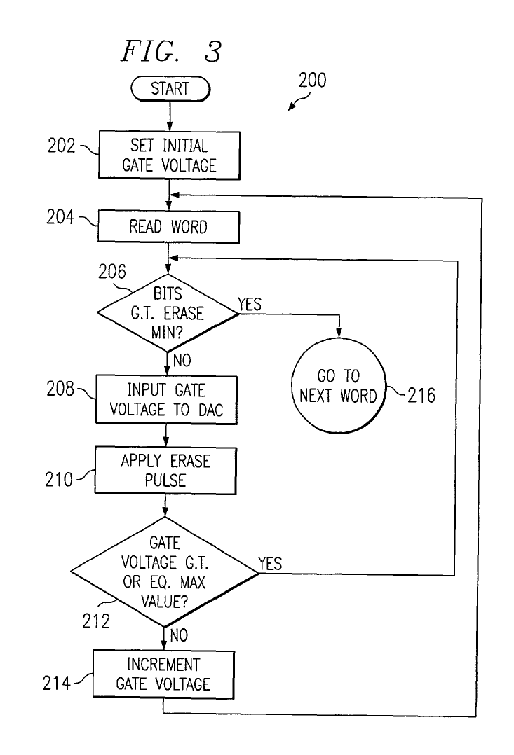

FIG. 3 is a flow diagram showing a method 200 that can be implemented, for example, by an execution unit (e.g., 108) of flash state machine 30 to perform an erase operation and minimize bit stress, in accordance with one embodiment of the present invention. The execution unit can be implemented by a suitable microprocessor. Read/write registers associated with the execution unit can be used to store default and maximum state machine values for program and erase operations. For example, a default erase pulse width value of 350 μs, and a maximum number of erase pulses (per erase operation) value of 3000, can be stored in these registers. For an erase operation, a host can select a starting erase pulse voltage, incremental erase pulse voltage, and final erase pulse voltage (e.g., represented by respective gate voltages) to be used. The host system can write these values to three 4-bit registers associated with the execution unit. A fourth register can be used to store a current erase pulse voltage value code. A 4-bit Digital-To-Analog Converter (DAC) can be used to convert the current erase pulse voltage value digital code to a voltage to be applied to the gates of the bit transistors to be erased. In an example practical implementation, a suitable starting voltage value code can be “0000” to generate a gate voltage of about −4.0V, a suitable ending voltage value code can be “1111” to generate a gate voltage of about −7.0V, and a suitable incremental voltage value code can be “0001”. For example, an incremental value of “0001” can linearly step up the gate voltage for each successive erase pulse from −4.0V to −7.0V in sixteen steps. As another example, an incremental value of “0010” can step up the gate voltage from −4.0V to −7.0V in eight equal steps, and so on. Advantageously, for optimum design flexibility, when the silicon for a flash memory is being characterized, an optimum value for the starting, ending, and incremental gate voltages can be determined and programmed for use, for example, by a state machine.

Referring to FIG. 3, at step 202 of example erase method 200, a processor associated with flash memory module 10 (e.g., microprocessor associated with execution unit 108) writes a starting value of a gate voltage for an erase pulse to a register. At step 204, the processor reads a word stored in a memory array to be erased. At step 206, the processor determines if the value of the bits in that word is greater than a predetermined minimum threshold erase value (e.g., word has been effectively “erased”). If not, at step 208, the processor inputs an initial gate voltage value (e.g., stored in a register) to a DAC, which generates a gate voltage based on the stored bit values (e.g., in the register). At step 210, the processor applies the generated gate voltage as an erase pulse to the bit transistor(s) in the memory array involved. At step 212, the processor determines if the value of the bits in the register is greater than or equal to a predetermined maximum threshold erase voltage value. If not, at step 214, the processor increments the current gate voltage value in the register by a fixed (incremental) voltage value. Returning to step 204, the processor again reads the word from the memory array being erased, and then performs step 206 to determine if the bits are below the minimum threshold erase value. If not, steps 208 through 214 are performed to generate and apply a successively larger erase pulse to the bit transistor(s) involved. A sequence of steps (e.g., steps 204 through 212) can be performed that incrementally increases the erase pulse gate voltage until (e.g., at step 212) an erase pulse gate voltage is generated that is equal to a predetermined maximum absolute threshold voltage value. Once the erase pulse gate voltage stored in the register reaches the predetermined maximum threshold voltage value, the processor continues applying erase pulses at this maximum threshold gate voltage until the entire memory array of interest is erased (e.g., reading all of the words in the array until they pass the minimum erase conditions (e.g., step 206)). In summary, in accordance with one embodiment of the present invention, a method and system for erasing flash memory and minimizing bit stress are provided that can incrementally increase the erase pulse voltage by a fixed amount until the flash memory is effectively erased.

Although a preferred embodiment of the method and apparatus of the present invention has been illustrated in the accompanying Drawings and described in the foregoing Detailed Description, it will be understood that the invention is not limited to the embodiment disclosed, but is capable of numerous rearrangements, modifications and substitutions without departing from the spirit of the invention as set forth and defined by the following claims.

What is claimed is:

1. A method for minimizing bit stress during an erase operation in a non-volatile memory, comprising the steps of:
generating an erase voltage;
applying said erase voltage to said non-volatile memory;
determining if said non-volatile memory has been erased;
if said non-volatile memory has not been erased, incrementing said erase voltage by a predetermined amount to form an incremented erase voltage, applying said incremented erase voltage to said non-volatile memory, and returning to the determining step; and
if, at the determining step, said non-volatile memory has been erased, terminating said erase operation.

2. The method of claim 1, wherein said non-volatile memory comprises a flash memory.

3. The method of claim 1, wherein said non-volatile memory comprises an EEPROM device.

4. The method of claim 1, wherein said non-volatile memory comprises at least one stacked gate transistor.

5. The method of claim 1, wherein the step of applying said erase voltage to said non-volatile memory comprises applying said erase voltage to a gate of at least one stacked gate transistor.

6. The method of claim 1, wherein said non-volatile memory comprises a memory sector.

7. The method of claim 1, wherein the steps are implemented by a state machine.

8. A system for minimizing bit stress during a memory erase operation, comprising:
a non-volatile memory; and
a processor coupled to said non-volatile memory, said processor operable to:
generate an erase voltage;
apply said erase voltage to said non-volatile memory;
determine if said non-volatile memory has been erased;
if said non-volatile memory has not been erased, increment said erase voltage by a predetermined amount to form an incremented erase voltage, apply said incremented erase voltage to said non-volatile memory, and return to the determine operation; and
if said non-volatile memory has been erased, terminate said memory erase operation.

9. The system of claim 8, wherein said non-volatile memory comprises a flash memory.

10. The system of claim 8, wherein said non-volatile memory comprises an EEPROM device.

11. The system of claim 8, wherein said non-volatile memory comprises at least one stacked gate transistor.

12. The system of claim 8, wherein the operation to apply said erase voltage to said non-volatile memory comprises an operation to apply said erase voltage to a gate of at least one stacked gate transistor.

13. The system of claim 8, wherein said non-volatile memory comprises a memory sector.

14. The system of claim 8, wherein said processor is associated with a state machine.
